(19) United States
(12) Patent Application Publication
(10) Pub. No.: US 2008/0133166 A1
(43) Pub. Date: Jun. 5, 2008

(54) Automatic testing method to be used by an IC testing system equipped with multiple testing sites

(75) Inventor: Angus Lai, Taoyuan Hsien (TW)

Correspondence Address: BACON & THOMAS, PLLC, 625 SLATERS LANE, FOURTH FLOOR, ALEXANDRIA, VA, 22314, US

(73) Assignee: CHROMA ATE INC., Taoyuan Hsien (TW)

(21) Appl. No.: 11/798,666

(22) Filed: May 16, 2007

(30) Foreign Application Priority Data
Nov. 30, 2006 (TW) 095144472

(51) Int. Cl. G01R 31/317; G06K 7/10

(52) U.S. Cl. 702/118; 235/462.01; 702/119

(57) ABSTRACT

An automatic testing method to be used by an IC testing system equipped with multiple testing sites. In this method the testing procedural information for each IC is stored in different sets of image files that are to be read by the testing system. Thus by inputting into the testing system the identification codes of the IC's that are going to be tested, the testing system would recognize which image files to use and the testing procedure would continue automatically. This method would greatly reduce the complex procedures needed to prepare an IC for testing in the prior art, thus leaving less room for human error and increasing the accuracy of the testing procedure.

### FIELD OF THE INVENTION

This invention relates to an automatic testing method to be used by an IC testing system, more particularly to an automatic testing method to be used by an IC testing system which has its testing apparatuses boot, retrieve programs and run programs from a central control module, thus not requiring a hard disk, CD ROM drive or floppy disk drive to be installed for each apparatus.

### BACKGROUND OF THE INVENTION

Integrated circuits have, without doubt, become the core of electronics nowadays. Consequently the reliability of an integrated circuit has a great impact on the reliability of the product it is utilized in.

Currently IC testers could be categorized into 2 different types. One type of IC testers tests the electrical properties of the IC, while another type of IC testers tests the IC under actual usage. Although the former method could thoroughly test the electrical properties of the IC, it also requires extensive hardware and software setup. Not only does this setup require a lot of resources, it also requires a lot of time to reconfigure when an IC has its design updated. Thus not only is this method costly, it is also hard to keep up with the rapidly changing electronic world.

The testing method that tests the IC under actual usage, on the other hand, does not seek to obtain the electrical properties of the tested IC, but rather tests if the IC would actually work for its given application. Although this testing method takes a longer time, it easily determines the performance of the tested IC under actual usage and whether the IC is ready to be installed. Also, it is relatively easy to create the IC testing apparatus, for its main component need only be a product that has the IC being tested removed. These products are readily available in the market. For example, if the tested IC is a CPU, then the testing apparatus would mainly consist of a motherboard which has its CPU removed.

As shown in FIG. 1, the testing method described above would include a central control module 10 which controls six testing apparatuses 11. Each testing apparatus includes a testing circuit board 110, a hard drive, and a computer network interface. The testing procedure is stored in each hard drive. Signals are sent back and forth between the central control module 10 and the testing circuit board 110 of each testing apparatus 11 via the computer network interface, thus allowing the central control module 10 to control each testing apparatus 11 and each testing apparatus 11 to send test results to the central control module 10. The central control module 10 then uses the test results to determine whether the tested IC meets the standards required.

Yet there are some flaws in this testing method. Whenever a change in the type of IC tested occurs, the network of the system must be reconfigured from the central control module 10 and the content of the hard drives of the testing apparatuses 11 must be updated. Hence this testing method requires a lot of manual effort and lacks efficiency.

Also, the hard drives of each testing apparatus 11 must be turned off in order to replace an IC that has finished testing with a non-tested IC and turned on again to test the IC. Thus the hard drives are constantly turned on and off as the testing system tests one IC after another, which makes the hard drives very susceptible to failure due to cyclic loading. Whenever this happens, the hard drive must be replaced by another which has the testing information installed onto it. If the wrong testing information is accidentally installed onto the hard drive, the testing procedure of the IC would be faulty. At its least, this error may lead to the rejection of a perfectly capable IC. At its worse, this error may lead to the acceptance of an incapable IC, which may lead to a faulty product line.

Also, there may be many product lines present in a single factory, thus it is highly possible that a testing system would need to test many different ICs. Whenever a change in the type of IC tested occurs, the information in the testing apparatuses must be updated, which makes the testing system vulnerable to the error described in the previous paragraph. In addition, a single worker must often man more than one testing system, which increases the probability of the error occurring.

If the configurations prior to the testing processes could be made automatic, then the chance of human error would be greatly reduced. If so then not only would the costs, efficiency and accuracy of interconnect tests be improved, the testing system itself would be a product of great potential.

### SUMMARY OF THE INVENTION

A primary objective of the present invention is to provide an automated testing method for an IC testing system with multiple testing sites with a reduced possibility of human error and need for human resources.

Another objective of the present invention is to provide an automated testing method for an IC testing system with multiple testing sites with high accuracy and efficiency. Another objective of the present invention is to provide an automated testing method for an IC testing system with multiple testing sites with reduced costs. Therefore, the automatic testing method to be used by an IC testing system equipped with multiple testing sites of the present invention, which could correspond to a plurality of testing circuit boards, wherein said testing circuit boards respectively correspond to a plurality of testing procedures whose numbers are less than those of the testing circuit boards, said testing system has a plurality of testing sites and a control device, said each testing site provides for installation of a testing circuit board respectively, and said testing circuit board has an ID code respectively; said method comprises installing the control device with a database of said each testing circuit board's ID code, testing procedure image files, and data linking each ID code to its pertinent image files; inputting the ID code of the testing circuit board of said each testing apparatus used in the test into said control device; providing the image file corresponding to said testing procedure, to which the testing circuit board of said each testing apparatus corresponds, for running said each testing apparatus by said control device. By using a central control module to control each testing apparatus and to send the correct testing process image file to each testing apparatus according to the testing circuit board's ID code, the role which human error may play in the testing process would be greatly reduced.

### BRIEF DESCRIPTION OF THE DRAWINGS

The present invention will be apparent to those skilled in the art by reading the following detailed description f a preferred embodiment thereof, with reference to the attached drawings, in which:

FIG. 1 is a perspective view showing an IC testing system with a central control module controlling six testing apparatuses.

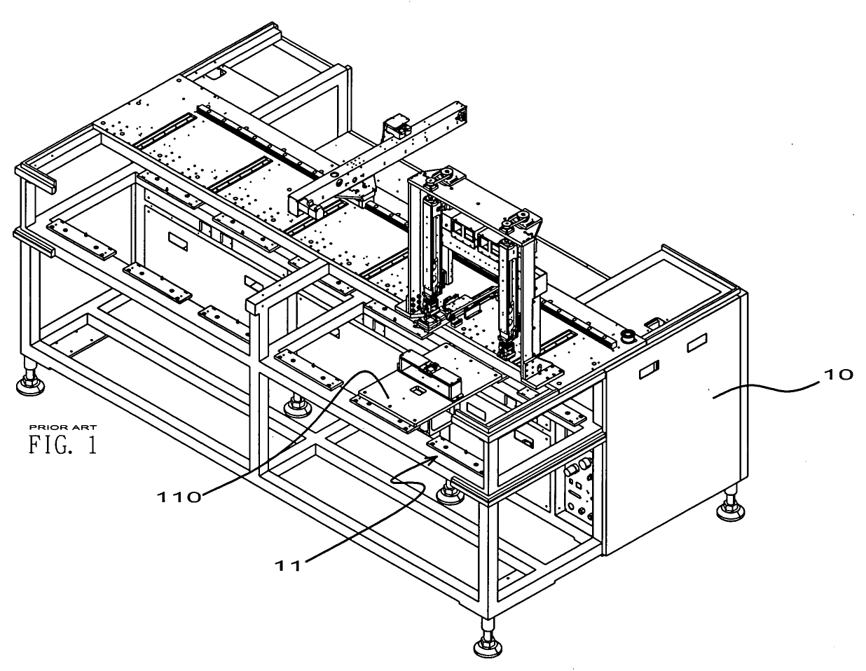

FIG. 2 is a plan view schematically showing a preferred embodiment of the IC testing system according to the present invention.

FIG. 3 is a flow chart illustrating a preferred embodiment of the IC testing method according to the present invention.

FIG. 4 is a block diagram explaining how the MAC codes of the testing circuit boards could be read by the control device.

### DETAILED DESCRIPTION OF THE PREFERRED EMBODIMENT

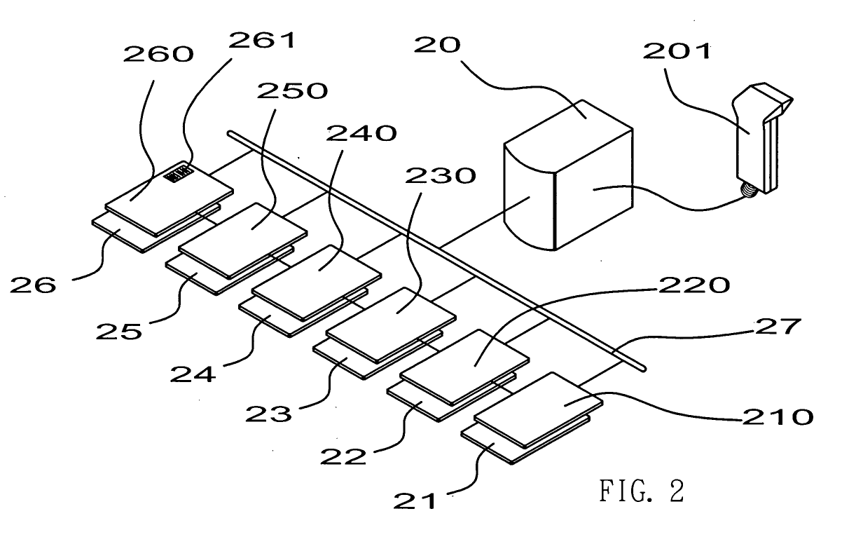

The first preferred embodiment of the automatic testing method to be used by an IC testing system equipped with multiple testing sites is shown in FIG. 2, which includes a control device 20, a bar code reading device 201, six testing apparatuses 21-26, and six separate testing circuit boards 210-260, one for each of the six testing apparatuses 21-26. Each testing circuit board 210-260 has an ID code. The control device 20 is connected via a communication means 27 to the testing circuit boards 210-260. The control device also has a device that could retrieve the ID codes from the circuit boards 210-260.

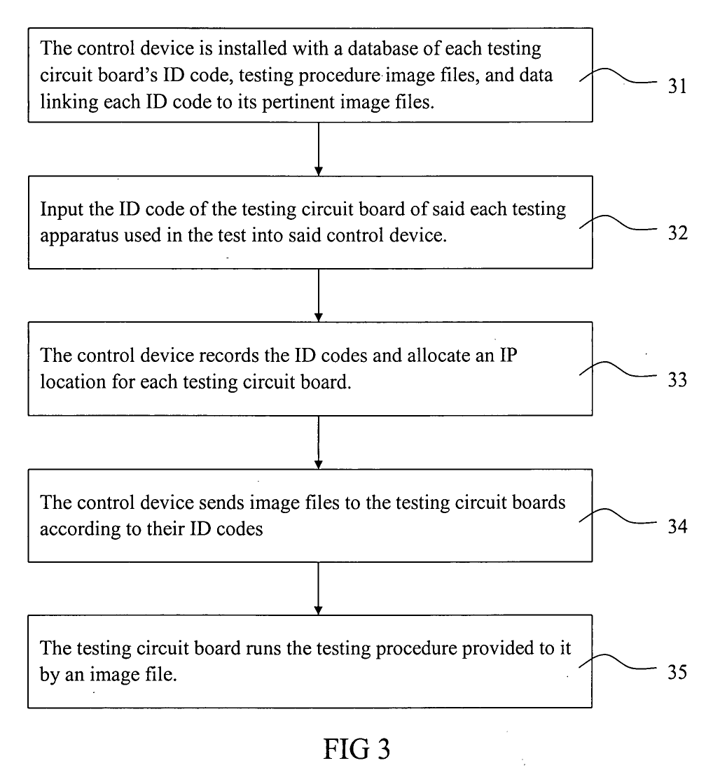

As shown in FIG. 3, before the testing system is run, the testing system must undergo step 31, where the control device 20 is installed with a database of each testing circuit board's ID code, testing procedure image files, and data linking each ID code to its pertinent image files. For example one testing system may need to test the CPU of a laptop, the IC of a video card, and the IC of a cell phone. For each product to be tested there may be one hundred testing circuit boards that could be used. In this case, the control device 20 of the testing system must be installed with three hundred ID codes for the testing circuit boards, three different testing procedure image files, and data linking each ID code to the image files it would use. In the end, the control device 20 would be able to load the image file corresponding to a circuit board once the control device 20 knows the ID code of the circuit board, thus removing the need of complex manual handling.

Right before running the testing system, step 32 must be completed, where the ID code of each testing circuit board used in the test is input into the control device. In this embodiment, the ID code is a bar code 261 that is located on the testing circuit board 260. The control device 20 is connected to a bar code reader 201, which would read the bar code and send it to the control device 20, thus allowing control device 20 to recognize which image files the six testing circuit boards 210-260 need.

In step 33, control device 20 would record the 6 ID codes and allocate an IP location for each testing circuit board 210-260. In step 34, the control device 20 would send image files to testing circuit boards 210-260 according to their ID codes. For example, if testing circuit boards 210-230 are meant to test a CPU and testing circuit boards 240-260 are meant to test a cell phone chip, control device 20 would send an image file for testing CPUs to testing circuit boards 210-230 and another image file for testing cell phone chips to testing circuit boards 240-260.

In the last step 35, the testing circuit board runs the testing procedure provided to it by an image file. Because all of the testing procedures have been loaded in the image file, there would be no need for reconfiguring the testing system before testing. Because the image file is loaded right before testing, the testing circuit boards do not need a hard drive to store testing procedures and configurations. One testing system could also test more than one type of IC by downloading different image files onto different testing apparatuses.

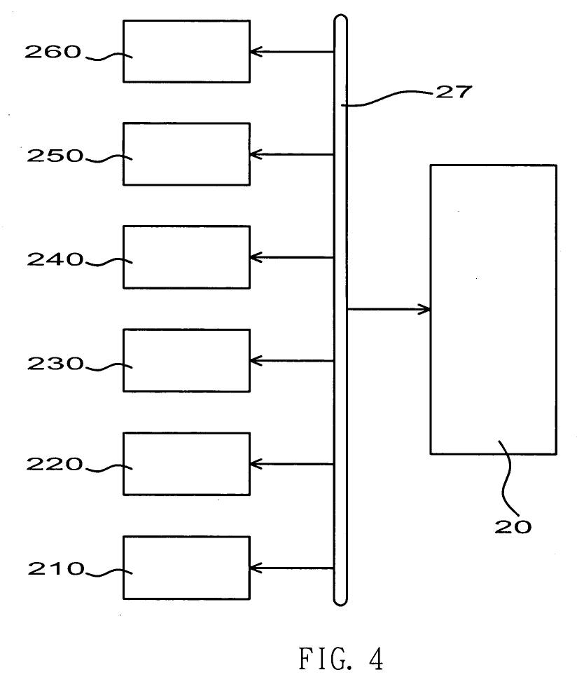

Of course, as shown in FIG. 4, the ID codes for testing circuit boards 210-260 could also be the codes on the MAC code of the computer network interface of each testing circuit board 210-260. If so, once the testing system is turned on, the control device 20 would use the communication means 27 to read the MAC codes of testing circuit boards 210-260. The control device 20 would then download the image files corresponding to each MAC code and continue the testing procedures.

By following the methods described above, the testing procedure of a testing system could be made more automatic, thus lowering costs of testing and equipment. The simplification of the organization mechanisms would greatly reduce the chance of human error, thus raising the accuracy and efficiency of the test, thus fulfilling the goals of this case. While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements

What is claimed is:

1. An automatic testing method to be used by an IC testing system equipped with multiple testing sites, which could correspond to a plurality of testing circuit boards, wherein said testing circuit boards respectively correspond to a plurality of testing procedures whose numbers are less than those of the testing circuit boards, said testing system has a plurality of testing sites and a control device, said each testing site provides for installation of a testing circuit board respectively, and said testing circuit board has an ID code respectively; said method comprises the steps of:
installing the control device with a database of said each testing circuit board's ID code, testing procedure image files, and data linking each ID code to its pertinent image files;
inputting the ID code of the testing circuit board of said each testing apparatus used in the test into said control device;
providing the image file corresponding to said testing procedure, to which the testing circuit board of said each testing apparatus corresponds, for running said each testing apparatus by said control device.

2. The automatic testing method to be used by an IC testing system equipped with multiple testing sites according to claim 1, wherein said ID code is a bar code.

3. The automatic testing method to be used by an IC testing system equipped with multiple testing sites according to claim 2, wherein said input method is reading bar codes by a scanner.

4. The automatic testing method to be used by an IC testing system equipped with multiple testing sites according to claim 1, wherein said ID codes are internal codes of a computer network interface.

5. The automatic testing method to be used by an IC testing system equipped with multiple testing sites describe in claim 4, wherein said input method is automatic reading when the system boots.
